(19) United States
(12) Patent Application Publication
(10) Pub. No.: US 2024/0008271 A1
(43) Pub. Date: Jan. 4, 2024

(54) SOLID-STATE OPTICAL STORAGE DEVICE

(71) Applicant: GenXComm, Inc., Austin, TX (US)

(72) Inventors: Brian Mattis, Austin, TX (US); Taran Huffman, Austin, TX (US); Bryan Woo, Goleta, CA (US); Thien-An Ngoc Nguyen, Austin, TX (US)

(21) Appl. No.: 17/977,939

(22) Filed: Oct. 31, 2022

Related U.S. Application Data
(60) Provisional application No. 63/356,935, filed on Jun. 29, 2022.

(51) Int. Cl. H01L 27/11526; G02B 6/43; G02B 6/42

(52) U.S. Cl. CPC H01L 27/11526; G02B 6/43; G02B 6/4202; G02B 6/4277

(57) ABSTRACT

A semiconductor device includes a floating gate that can be charged in a nonvolatile manner. The floating gate is also structured as an optical waveguide, and may be optically coupled to a photonic circuit, such as an interferometer.

### CROSS REFERENCE TO RELATED APPLICATION

This application is a nonprovisional of and claims the benefit under 35 U.S.C. § 119 of U.S. Provisional Patent Application No. 63/356,935, filed Jun. 29, 2022, entitled “Solid-State Device with Optical Waveguide as Floating Gate Electrode,” the contents of which is incorporated by reference in its entirety.

### TECHNICAL FIELD

Embodiments described herein relate to solid-state photonic devices that include one or more optical waveguides configured as floating gates for nonvolatile storage of electrical charge.

### BACKGROUND

Semiconductor devices can include a floating gate that can be electrically charged or discharged via quantum mechanical tunneling through an insulator layer. More specifically, a control gate electrode, disposed over the insulator layer, can be driven to a specified voltage to induce or remove charge carriers from the floating gate. In these constructions, the charge state of the floating gate can be used as nonvolatile memory for a digital circuit.

In some applications, a photonic circuit may be selected to replace a semiconductor circuit to reduce power consumption and/or improve performance. A photonic circuit can include a number of optical waveguides configured to direct light to, and between, one or more passive or active optical circuits, photonic circuits, delay loops, input/output facets, and so on. Conventional photonic circuits, however, are incapable of being implemented as nonvolatile memory.

### SUMMARY

Embodiments described herein can take the form of a semiconductor device including at least a source electrode, a control electrode, an insulator layer, and a floating gate separated from the source electrode and the control electrode by the insulator layer. For constructions described herein, the floating gate is an optical waveguide optically coupled to, and conductively decoupled from, a photonic circuit.

In these constructions, the floating gate can be charged or discharged through the insulator layer via quantum tunneling (e.g., Fowler-Nordheim tunneling, hot carrier injection, direct bandgap tunnelling, or thermionic emission). As a result of electrical isolation of the floating gate due to the insulator layer(s), the floating gate retains its charged or uncharged state in a nonvolatile manner. The retained charge can be leveraged as traditional nonvolatile electronic memory and/or can be leveraged to change one or more properties of light propagating through the floating gate/optical waveguide so as to function as a programmable optical switch (e.g., when operated as or with a Mach-Zehnder interferometer structure). More generally, a structure as described herein can be used as optical nonvolatile memory and/or as electrical nonvolatile memory.

More broadly, for constructions described herein, the floating gate also functions as an optical waveguide. As may be known to a person of skill in the art, presence or absence of electrical charge in an optical waveguide influences an index of refraction of that optical waveguide. As a result of this electro-optic effect, the refractive index of the optical waveguide/floating gate is different between a charged state or an uncharged state of the floating gate. Further, because the charged state or uncharged state of the floating gate is nonvolatile, the index of refraction of the optical waveguide is also modifiable/mutable in a nonvolatile manner. In this way, the optical waveguide can function as a portion of a nonvolatile optical switch.

More generally and broadly, constructions described herein can be leveraged to form nonvolatile memory cells for photonic circuits.

Related and additional embodiments may include a configuration in which the insulator layer includes a first portion separating the source electrode from the floating gate and a second portion separating the control electrode from the floating gate. The first and second portions can be formed to different thicknesses to encourage charge to remain in the floating gate/optical waveguide. In other cases, the second portion of the insulator layer may be an oxide-nitride-oxide dielectric layer, a nitride/oxide/nitride layer set, and/or an oxide/alumna/oxide layer. More generally, any suitable insulator layers may be used.

In some embodiments, implants may be used in and/or near the floating gate to encourage electrical charge to accumulate within a waveguide portion of the floating gate. The implants may be positioned in a single location, multiple locations, or in a pattern. In some cases, implants may take a shape such as a shape following a perimeter of a floating gate as described herein. The implants can have any suitable charge polarity or combinations of charge polarities (e.g., regions of charge); a person of skill in the art will readily appreciate that many suitable configurations are possible.

As noted above, in some constructions, a photonic circuit including an optical waveguide includes an interferometer, such as a Mach-Zehnder interferometer or a ring resonator as non-limiting examples. In these examples, a charge state of the optical waveguide/floating gate either introduces, or does not introduce, a phase shift in light passing therethrough (e.g., infrared light). By branching light input to the photonic circuit through two or more paths, one of which passes through the optical waveguide/floating gate, and recombining those paths at one or more outputs, any phase shift introduced by the optical waveguide/floating gate causes constructive or destructive interference at the recombined output(s), determining how much light each outputs. In a simpler phrasing, the charge state of the floating gate controls, in a nonvolatile manner, how (or whether) light passes through the photonic circuit.

Embodiments described herein can also take the form of a semiconductor device including at least a conductive element, a layered dielectric disposed below the conductive element, and a silicon waveguide formed to interface a silicon oxide layer of the layered dielectric. As with other examples, the silicon waveguide can be optically coupled to a photonic circuit (such as a Mach-Zehnder interferometer, a ring resonator, and so on).

Also, as with other embodiments described herein, the silicon waveguide can be conductively decoupled from the conductive element. As a result of this construction, in response to a voltage applied to the conductive element, the silicon waveguide accumulates charge by quantum tunneling that effects a change in a refractive index of the silicon waveguide. This change in refractive index can be used as nonvolatile optical memory and/or a nonvolatile optical switch. In higher-order constructions, semiconductor devices such as described herein can be leveraged in silicon and/or photonic circuits, such as memory cells, field-programmable photonic gate arrays, adjustable frequency filters, and so on. Any suitable photonic circuit, of any suitable complexity or scale, can be implemented to leverage the systems and methods described herein.

### BRIEF DESCRIPTION OF THE DRAWINGS

Reference will now be made to representative embodiments illustrated in the accompanying figures. It should be understood that the following descriptions are not intended to limit this disclosure to one included embodiment. To the contrary, the disclosure provided herein is intended to cover alternatives, modifications, and equivalents as may be included within the spirit and scope of the described embodiments, and as defined by the appended claims.

FIG. 1A depicts a simplified cross section of a nonvolatile programmable passive optical structure for a photonic circuit, such as described herein.

FIG. 1B depicts a simplified side view of a floating gate/optical waveguide such as described herein.

FIGS. 2A-2D each depict a simplified schematic view of an optical waveguide that may optically couple to a nonvolatile programmable passive optical structure for a photonic circuit, such as described herein.

FIGS. 3A-3C each depict a simplified illustration of an optical waveguide that may optically couple an optical fiber to an electrically isolated nonvolatile programmable passive optical structure for a photonic circuit, such as described herein.

FIGS. 4A-4E each depict a simplified system diagram of a nonvolatile programmable passive optical structure for a photonic circuit, as described herein.

FIGS. 5A-5C each depict a simplified schematic view of an interferometer structure as described herein.

FIGS. 6A-6B depict simplified cross sections of a nonvolatile programmable passive optical structure for a photonic circuit with a charge attracting electrode, such as described herein.

FIG. 7 is a flowchart depicting example operations of a method of operating a nonvolatile programmable passive optical structure, such as described herein.

FIG. 8 is a flowchart depicting example operations of a method of operating a nonvolatile programmable passive optical structure with a photonic circuit, such as described herein.

FIG. 9 is a flowchart depicting example operations of a method of operating a nonvolatile programmable passive optical structure with a photonic circuit, such as described herein.

FIG. 10 is a flowchart depicting example operations of a method of manufacturing a nonvolatile programmable passive optical structure with a photonic circuit, such as described herein.

FIG. 11 is a flowchart depicting example operations of a method of manufacturing a nonvolatile programmable passive optical structure with a photonic circuit, such as described herein.

FIG. 12 is a flowchart depicting example operations of a method of operating a nonvolatile programmable passive optical structure, such as described herein.

The use of the same or similar reference numerals in different figures indicates similar, related, or identical items.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Certain accompanying figures include or imply vectors, rays, traces and/or other visual representations of one or more example paths—which may include reflections, refractions, diffractions, and so on, through one or more mediums—that may be taken by, or may be presented to represent, one or more photons, wavelets, or other propagating electromagnetic energy originating from, or generated by, one or more light sources shown or, or in some cases, omitted from, the accompanying figures.

It is understood that these simplified visual representations of light or optical paths or, more generally, electromagnetic energy or waveguides for the same, regardless of spectrum (e.g., ultraviolet, visible light, infrared, and so on), are provided merely to facilitate an understanding of the various embodiments described herein and, accordingly, may not necessarily be presented or illustrated to scale or with angular precision or accuracy, and, as such, are not intended to indicate any preference or requirement for an illustrated embodiment to receive, emit, reflect, refract, focus, and/or diffract light at any particular illustrated angle, orientation, polarization, color, or direction, to the exclusion of other embodiments described or referenced herein.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Embodiments described herein relate to phonic circuits and structures having optical properties that are stable, and nonvolatile, in two or more states. Such structures can be leveraged by a photonic circuit for nonvolatile field configuration or nonvolatile storage, such as in one or more optical memory cells, one or more arrays of memory cells, one or more configurable logic blocks of a field-programmable gate array, one or more bistable switch elements, and so on.

More generally, a person of skill in the art may readily appreciate that an optical element that exhibits an electrically-programmable, nonvolatile, optical property can be used in countless ways in photonic, electronic circuits, and combinations thereof.

For example, a programmable optical element can be operated along one branch of an interferometer. In this example, output of the interferometer depends upon a state of the programmable optical element. In one example, the programmable optical element may operate in a first state (e.g., a charged state) to impart a phase shift to light passing through that branch of the interferometer. When this light recombines with light passing through another branch of the interferometer, it may destructively interfere. Conversely, if the programmable optical element is operated in a second state (e.g., an uncharged state), no phase shift may be imparted and no destructive interference may occur. In this manner, the optical element may block light or pass light depending upon its charged state.

In one example embodiment, an array of programmable optical elements such as described above can be manufactured together. In one example, a photodiode can be manufactured and/or optically coupled to an optical output of each respective optical element. In this manner, when a single laser light pulse is provided as input to the entire array, each and every optical element either permits light to pass to the respective photodiode or blocks light from hitting the respective photodiode. In this manner, a state of each individual optical element can be simultaneously (e.g., in parallel) read into an electrical memory, while the device itself consumes only the electrical power necessary to drive the laser pulse.

A person of skill in the art may further readily appreciate that any photonic logic circuit can be constructed from a suitable combination of optical logic gates, each of which may have one or more programmable behaviors, such as described herein. More generally, any optical element as described herein can programmatically augment one or more optical properties of light passing through that optical element.

Further, because such properties are nonvolatile, photonic circuits that incorporate these elements can be operated at significantly reduced power compared to electrically-switched photonic circuits which, as known to a person of skill in the art, already exhibit significantly reduced power as compared to semiconductor circuits.

More specifically, a photonic circuit as described herein can be operated, and may perform one or more functions, while consuming only a quantity of electrical power required to generate light that passes through that photonic circuit and/or electrical power required to convert that light into one or more electrical signals. In other words, embodiments described herein can be leveraged to create passive optical circuits that are electrically programmable and that, once programmed, do not require significant electrical power to maintain state or function.

For example, as noted above, a single bistable optical element as described herein can be programmatically configured to either pass light or to block light. More specifically, once programmed and regardless of electrical power state, the bistable optical element either passes light or blocks light provided to it as optical input. This controllable optical property can be leveraged as a bit of digital memory, a control gate for enabling or disabling other photonic circuit elements optically coupled to the bistable optical element, a pixel of a no-power digital image, or for any other suitable purpose.

In other examples, an array of bistable optical elements can be used to create a nonvolatile digital memory cell or a nonvolatile memory cell array, storing in a durable manner any suitable quantity of digital data.

In yet other examples, bistability may not be required or preferred. For example, a programmable optical element as described herein can be programmatically configured to attenuate light by a particular programmed amount, or switch entirely between two or more optical outputs. More specifically, once programmed and regardless of electrical power state, the optical element can be configured to attenuate light provided to it by a specified amount. This controllable optical property can be leveraged as a portion of (e.g., a node or a layer of) a trained neural network or other machine learning data structure. More generally and broadly, an array of optical elements as described herein can be programmed to perform—as a passive optical structure—any machine-learned or training-informed computational function.

For example, a photonic integrated circuit as described herein can be formed as a multilayer neural network. Each node/neuron of the neural network can receive multiple inputs and may be configured to attenuate those inputs by a certain amount (e.g., corresponding to an activation of that neuron), and provide output to multiple optical outputs. In this manner, a neural network, and its hidden layers and its neuron connections, can be dynamically programmed to perform any suitable artificial intelligence or machine learning task.

Structures which may be referred to herein as “nonvolatile programmable passive optical structures,” are particularly useful in low-power applications, such as in edge-compute devices and small electronics (e.g., personal electronics, robotics, drones, Internet-of-Things devices, satellites, and so on). In other cases, devices as described herein may be useful for service in conditions that are not suitable for conventional electronic devices. In other implementations, a nonvolatile programmable passive optical structure as described herein can be used for large-scale, power efficient, data storage.

In yet other examples, a nonvolatile programmable passive optical structure or network thereof can be used in, or as, a trained neural network or other training informed machine learning system configured for one or more of: signal analysis (e.g., Fourier or other transforms, encoding, decoding, modulation, demodulation, encryption, decryption, and so on); cryptographic calculations (e.g., cryptocurrency mining, data encryption or decryption); self-driving; image recognition; voice recognition; drone or robotics command and/or control; global positioning calculations; hardware virtualization; network switching; or for any other suitable computing or control task.

As such, generally and broadly, it may be appreciated that a nonvolatile programmable passive optical structure or network of such structures as described herein can be programmed to optically/physically implement a neural network or other trained machine learning structure or, more generally, any digital or analog logic structure or network of digital or analog logic structures.

Further, a nonvolatile programmable passive optical structure can be used in, or with, any suitable computing resource configured to perform any computational operation or function. As used herein, the term “computing resource” (along with other similar terms and phrases, including, but not limited to, “computing device” and “computing network”) may be used to refer to any physical electronic device or machine component, or set or group of interconnected and/or communicably coupled physical electronic devices or machine components, suitable to execute or cause to be executed one or more arithmetic or logical operations on digital data or analog signals.

Example computing resources that incorporate one or more nonvolatile programmable passive optical structures as contemplated herein include, but are not limited to: single or multi-core processors; single or multi-thread processors; purpose-configured co-processors (e.g., graphics processing units, motion processing units, sensor processing units, and the like); configurable logic units (e.g., of field-programmable gate arrays); memory cells; volatile or nonvolatile memory or memory cells or arrays of cells; application-specific integrated circuits; field-programmable gate arrays; input/output devices and systems and components thereof (e.g., keyboards, mice, trackpads, generic human interface devices, video cameras, microphones, speakers, and the like); networking appliances and systems and components thereof (e.g., routers, switches, firewalls, packet shapers, content filters, network interface controllers or cards, access points, modems, and the like); embedded devices and systems and components thereof (e.g., system(s)-on-chip, Internet-of-Things devices, and the like); industrial control or automation devices and systems and components thereof (e.g., programmable logic controllers, programmable relays, supervisory control and data acquisition controllers, discrete controllers, and the like); vehicle or aeronautical control devices and systems and components thereof (e.g., navigation devices, safety devices or controllers, security devices, and the like); corporate or business infrastructure devices or appliances (e.g., private branch exchange devices, voice-over internet protocol hosts and controllers, end-user terminals, and the like); personal electronic devices and systems and components thereof (e.g., cellular phones, tablet computers, desktop computers, laptop computers, wearable devices); personal electronic devices and accessories thereof (e.g., peripheral input devices, wearable devices, implantable devices, medical devices and so on); and so on. It may be appreciated that the foregoing examples are not exhaustive.

In view of the foregoing, it may be appreciated that, generally and broadly, a nonvolatile programmable passive optical structure as described herein can be leveraged as a fundamental component of any number of photonic circuits.

As such, for simplicity of description and illustration, the embodiments that follow reference a nonvolatile programmable passive optical structure implemented as a portion of a Mach-Zehnder Interferometer for use as an optical switch, configured to direct light down one of two output paths, depending on the programmed state.

In these examples, the nonvolatile programmable passive optical structure is stable relative to each respective output (e.g., configured to pass light or to block light from that output, depending on the programmed state), and may be configured to operate as a digital, nonvolatile optical switch. It is appreciated, however that this is merely one example construction. In other cases, ring resonators or chains thereof can be used in place of or in addition to an interferometer structure.

In this example construction, the nonvolatile programmable passive optical structure has at least one optical input and at least one optical output. At least one of the optical inputs and at least one of the optical outputs are optically coupled to one or more other components of a photonic circuit, which may vary from embodiment to embodiment.

The optical inputs of the nonvolatile programmable passive optical structure can be coupled into a single path and thereafter branched into two arms (of equal length) in order to implement an interferometer structure. The first arm and the second arm are thereafter recombined through a second coupler. As a result of this construction, any phase difference between the first arm and the second arm causes destructive or constructive interferences at the optical outputs, changing relative power output between optical outputs.

A person of skill in the art may readily appreciate that several optical, mechanical, or electrical properties can be leveraged to introduce a phase shift in either the first arm or the second arm, thereby introducing a phase difference between the arms of the interferometer structure, as described above. Examples include the thermo-optic effects, thermal expansion/contraction, electro-optic effects, optional delay loops, and so on.

In other cases, a nonvolatile programmable passive optical structure as described herein can include one or more ring resonators. In these constructions, one or more closed-loop optical waveguides can be positioned/disposed near to one or more other (typically linear, although this is not required) waveguides.

Due to proximity between the closed-loop waveguide and the one or more other waveguides, light couples between them. As known to a person of skill in the art, certain frequencies of light (which vary from ring resonator to ring resonator) will constructively interfere on each successive round trip through each closed-loop waveguide, achieving resonance therein. As a result of this construction, both the geometry or optical properties of each ring resonator affect what frequencies of light resonate in each respective ring resonator.

Similarly to foregoing examples, a person of skill in the art may readily appreciate that several optical, mechanical (thermal), or electrical properties can be leveraged to introduce a change in resonant frequency of a ring resonator, as described herein. Examples include the thermo-optic effects, thermal expansion/contraction, electro-optic effects, optional delay loops, and so on.

Embodiments described herein reference methods and structures for leveraging the electro-optic effect (in which presence of an electric field induces a change in effective refractive index of an optical waveguide, thereby imparting a phase shift to light passing therethrough) to introduce a controllable phase difference between two arms of an optical interferometer structure, within a ring resonator, or any other suitable optical structure, such as described above.

Specifically, in these embodiments, one arm of an interferometer structure—or more particularly, at least a portion of one arm of an interferometer structure—is configured to operate as a floating gate formed from semiconductor material that is encapsulated in an insulator, such as silicon dioxide. As a result of this encapsulation, the floating gate can be used to store electrical charge in a nonvolatile way because no electrical path exists for any accumulated charge in the floating gate to dissipate.

Charge can be accumulated in the floating gate, despite that the floating gate is encapsulated by the insulator layer, by quantum tunneling, such as via Fowler-Nordheim tunneling or hot carrier injection across the potential barrier (i.e., insulator) surrounding the floating gate.

More specifically, in many constructions, a source electrode and a control electrode can be disposed over the insulator layer encapsulating the floating gate. As a result of this construction, a voltage of implementation-specific and/or design-specific magnitude applied at the control electrode can induce one or more charge carriers to tunnel through the insulator layer between the source electrode and the floating gate, and accumulate or reduce charge carriers in the floating gate.

Similarly, applying an opposite voltage at the control electrode can induce one or more charge carriers to tunnel in the opposite direction between the floating gate and the source electrode, thereby changing the charge state of the floating gate again.

For convention herein, applying a signal to the control electrode that induces the charge state of the floating gate to change to a specified/desired value may be referred to as a “write” or an “erase” operation or, more generally, a “programming” operation. Similarly, applying signal to the control electrode that induces the charge state of the floating gate to change to a default value may be referred to herein as an “erase” operation or a “reset” operation.

As noted above, the floating gate can, in many implementations, be optically coupled to one arm of an interferometer structure. In another phrasing, a floating gate can also serve as an optical waveguide in the optical path defined by one arm of an interferometer structure.

As a result of this architecture—in which an optical waveguide is also a floating gate configured to accumulate charge and retain that charge in a nonvolatile manner—a phase shift will be imparted in the first arm in proportion to the accumulated charge of the floating gate. The accumulated charge, in turn, results in a phase difference between the first and second arms of the interferometer structure which, in turn, destructively interferes at the optical output of the nonvolatile programmable passive optical structure.

By selecting a size and/or charge state of the floating gate to impart up to a 180° phase difference, the optical interferometer structure can be used as a nonvolatile bistable switch element; in a first charge state, light passes through the optical interferometer structure whereas in a second charge state, light destructively interferes and does not pass through the optical interferometer structure. In other constructions, an optical interferometer structure can include multiple optical outputs; in such examples, in a first charge state, light passes through to a first output and in a second charge state, light passes through to a second output. In yet other examples, intermediate charge states can each be associated with different optical power output from each output.

As such, more generally and broadly, embodiments described herein can take the form of a semiconductor device including at least a source electrode, a control electrode, an insulator layer, and a floating gate separated from the source electrode and the control electrode by the insulator layer. For constructions described herein, the floating gate is an optical waveguide optically coupled to, or into, a photonic circuit.

In these constructions, the floating gate can be charged or discharged (programmed or erased) through the insulator layer via quantum tunneling (e.g., Fowler-Nordheim tunneling and/or hot carrier injection). As a result of electrical isolation of the floating gate due to the insulator layer, the floating gate retains its charged or uncharged state in a nonvolatile manner.

As noted above, for these constructions, the floating gate also functions as an optical waveguide. As a result of the electro-optic effect, the refractive index of the optical waveguide/floating gate is different between a charged state or an uncharged state of the floating gate. Further, because the charged state or uncharged state of the floating gate is nonvolatile, the effective index of refraction of the optical waveguide is also modifiable/mutable in a nonvolatile manner. In this way, the optical waveguide can function as a portion of a nonvolatile optical switch, such as described above.

It may be appreciated that a nonvolatile programmable passive optical structure can be included in a number of photonic circuits and/or semiconductor circuits for any number of optical or electrical purposes or functions. For example, as noted above, an interferometer structure is merely one example optical structure that can leverage the methods and techniques described herein. In a ring resonator construction, one or more closed-loop waveguides (rings) can be implemented as a floating gate, as described herein. In other constructions, a portion of a closed-loop waveguide can pass through and/or be optically coupled to a floating gate/optical waveguide as described herein.

Furthermore, in some example constructions, a semiconductor device that includes a nonvolatile programmable passive optical structure as described herein (including at least one floating gate that doubles as an optical waveguide) can also include a drain gate. In these example constructions, the electrical field generated by charge accumulated in the floating gate can be measured electrically or optically by determining electrical characteristics of voltage differences between the drain and the source. In other words, in these constructions, the floating gate can be operated as optical memory or as electrical memory (e.g., flash memory).

In some implementations, operating a control gate to accumulate charge in the floating gate/waveguide during a write operation may be a time-consuming process; in such examples, the nonvolatile programmable passive optical structure may be electrically readable via the drain gate before becoming optically readable via a photonic circuit optically coupled thereto. In these constructions, different read operations or modes (i.e., electrical and optical) may be leveraged to improve overall performance or device responsiveness. For example, electrical read may be performed until the floating gate is sufficiently charged to affect an optical read operation. In other cases, an electrical read operation can be performed to verify an optical read operation. In other cases, an optical read operation can be performed to verify an electrical read operation. In yet other examples, an optical read operation can be performed to verify electrical read operations.

A person of skill in the art may appreciate that many different read and write techniques, whether electrical or optical are possible.

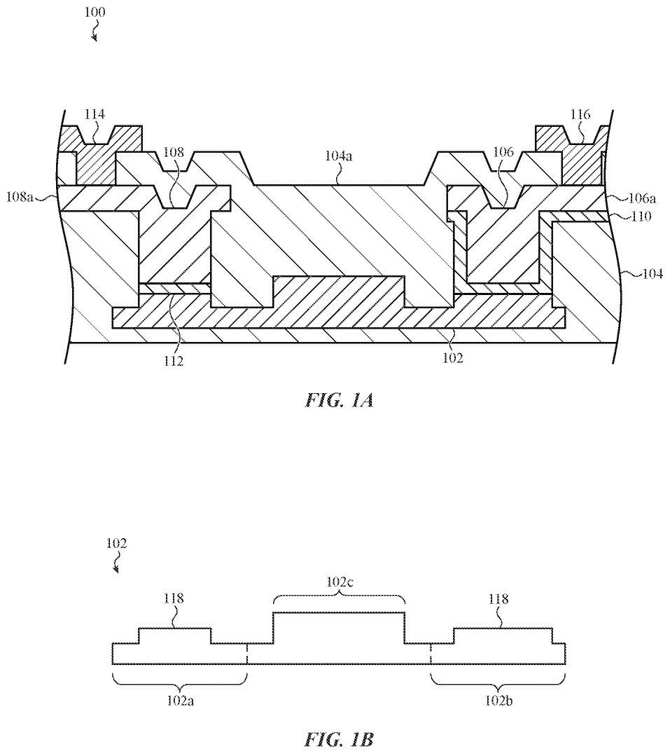

These and other constructions including a nonvolatile programmable passive optical structure are discussed below with reference to FIGS. 1A-12. However, those skilled in the art will readily appreciate that the detailed description given herein with respect to these figures is for explanation only and should not be construed as limiting.

Generally and broadly, FIGS. 1A-5C depict and/or relate to an example semiconductor structure that can include a nonvolatile programmable passive optical structure, such as described herein. For simplicity of description and illustration, the nonvolatile programmable passive optical structure depicted and described is implemented as a nonvolatile memory cell or nonvolatile optical switch, but as noted above, this is merely one example construction and other implementations are possible.

FIG. 1A depicts a simplified cross section of a nonvolatile programmable passive optical structure 100 for a photonic circuit, such as described herein. The nonvolatile programmable passive optical structure 100 can be included as a portion of any suitable electronic or photonic circuit.

The nonvolatile programmable passive optical structure 100 includes an optical waveguide 102. The optical waveguide 102 can be a rib waveguide or may take any suitable optical waveguide shape. The optical waveguide 102 can be formed from any suitable material although in many embodiments, crystalline silicon may be used. As such, in many examples, the optical waveguide 102 is a silicon optical waveguide.

The optical waveguide 102 is embedded in an insulator layer 104, which may be a silicon oxide, such as silicon dioxide. Thicknesses of cladding/encapsulation of the optical waveguide 102 may vary from location to location and embodiment to embodiment.

The optical waveguide 102 can include a rib portion and two wing portions, extending from the rib portion. The rib portion is depicted in the center of the optical waveguide 102, but this may not be required of all embodiments. In some examples, the optical waveguide 102 may be offset relative to the depicted position.

The optical waveguide 102 can be formed using any suitable technique. In some examples, the optical waveguide 102 is formed over a silicon oxide region of an initial substrate. In other cases, the optical waveguide 102 can be formed in a first process, after which the insulator layer 104 is formed around the optical waveguide 102. A person of skill in the art may readily appreciate that any suitable silicon manufacturing or micromachining technique can be used to form one or more features of the optical waveguide 102 and dispose the optical waveguide 102 within the insulator layer 104.

The nonvolatile programmable passive optical structure 100 further includes a control electrode 106 and a source electrode 108, each formed from a conductor or semiconductor material such as polycrystalline silicon or metals. The control electrode 106 can be separated from (e.g., electrically decoupled from) the optical waveguide 102 by a dielectric layer 110, and the source electrode 108 can be separated from (e.g., electrically decoupled from) the optical waveguide 102 by a dielectric layer 112.

In some examples, the dielectric layer 110 and the dielectric layer 112 can be formed from a silicon oxide. In further cases, the dielectric layer 110 and the dielectric layer 112 can be formed from the same material as the insulator layer 104.

In some embodiments the dielectric layer 110 and the dielectric layer 112 can be formed to different thicknesses; in typical implementations, the dielectric layer 110 can be formed to a greater thickness than the dielectric layer 112, but this may not be required of all embodiments.

In other cases, the dielectric layer 110 and the dielectric layer 112 may be formed from different materials or different combinations of materials. In one embodiment, the dielectric layer 110 is formed as a layered substrate including a first section/layer of a silicon oxide, a second section/layer formed from a silicon nitride, and a third section/layer formed from a silicon oxide.

In many constructions, the dielectric layer 110 and the dielectric layer 112 can be disposed over raised/elevated portions of the optical waveguide 102. More specifically, the optical waveguide 102 can be formed with three structural features—a first wing, a second wing, and a central waveguide region. The central region may be strip waveguide, or another suitable waveguide.

In this construction, a first wing and a second wing can be formed with an elevated region (e.g., sometimes referred to as a tabletop or mesa structure). The elevated region can be formed to improve manufacturing reliability. More specifically, in many cases, features of the optical waveguide 102 may be formed before other features of the structure 100. During subtractive processing used for feature definition in the optical waveguide 102, a roughening can occur in the etched (lowered) regions, impacting the quality of the surfaces underneath dielectric layers 110 and 112. In many cases, during manufacturing, the optical waveguide 102 may be encapsulated or buried in a dielectric material such as silicon dioxide. Thereafter, the dielectric material (also referred to as a cladding) may be etched through in order to define other elements, such as the control electrode 106 and the source electrode 108 and/or the dielectric layer 110 and the dielectric layer 112.

In many cases, a dry etch process may be used. However, in many cases, dry etch may not be particularly selective to the cladding material and may therefore at least partially etch the optical waveguide 102, roughening its surface and decreasing its optical performance and electrical performance. For example, in some cases, the optical waveguide 102 may locally vary in thickness, which in turn may cause the dielectric layer 110 and the dielectric layer 112 to locally vary in thickness, which, in turn, may result in poor tunneling performance.

In these examples, to improve performance, careful and precise timing of the dry etch process is often required. In these cases, the elevated portions of the optical waveguide 102 can increase a thickness of the optical waveguide 102, thereby increasing timing tolerance for a dry etch process.

In further embodiments, however, wet etch may be used such as a hydrofluoric acid etch. In these cases, the etchant may be highly selective to silicon dioxide (or other insulator materials/cladding materials) and may, therefore, leave a smooth surface for the optical waveguide 102. In these cases, a wet etch may improve both optical performance and electrical performance of the structure 100. More specifically, due to the smooth surface of the optical waveguide 102, the dielectric layer 110 and the dielectric layer 112 may be disposed to precise and even thickness.

In other cases, dry etch and wet etch can be used together (e.g., in sequence), so as to leverage benefits of both processes. For example, dry etch may be used first, followed by a wet etch process. Different embodiments may use different etching processes for different durations; many constructions are possible. In one example, dry etch may be used for 90% of a process duration; wet etch may finish the etch process for the remaining 10%. It may be appreciated however, that this is merely one example; any other combination of two or more alternations between wet and dry processes are possible, for any respective suitable durations of time.

In a more specific phasing, a first layer of silicon oxide can be formed to interface a wing region of the optical waveguide 102, a layer of a silicon nitride can be formed to interface the first layer of silicon oxide, and a second layer of silicon oxide can be formed to interface the silicon nitride layer and the control electrode 106.

As with the optical waveguide 102, the dielectric layer 110, the dielectric layer 112, the control electrode 106, and the source electrode 108 can all be formed in a number of suitable ways, to any number of suitable thicknesses, from any number of suitable materials, and so on. It may be appreciated that the illustrated cross section is merely one simplified example.

In many cases, the control electrode 106 and the source electrode 108 and each respective dielectric layer separating the electrodes from the optical waveguide 102, are also encapsulated within the insulator layer 104. This architecture may be selected to passivate the control electrode 106 and the source electrode 108 and prevent corrosion damage thereto.

Each of the control electrode 106 and the source electrode 108 can be conductively coupled to one or more metallized portions, such as the metallized region 114 and the metallized region 116. In some examples, the control electrode 106 can include an extended portion 106a to which the metallized region 116 extends through a via to conductively couple to the control electrode 106. Similarly, the source electrode 108 can include an extended portion 108a to which the metallized region 114 extends through a separate via to conductively couple to source electrode 108. The metallized portions can be formed from any suitable metals such as gold or aluminum.

The nonvolatile programmable passive optical structure 100 can be coupled to an electrical circuit configured to perform one or more write or erase operations. In particular, the electrical circuit—which may be referred to as a state controller—may be configured to apply a voltage signal of design-specific or implementation-specific magnitude relative to system ground, to the control electrode 106 via the metallized region 116.

When the voltage signal is applied, one or more charge carriers may be induced to tunnel through the dielectric layer 112 between the optical waveguide 102 and the source electrode 108. In these examples, the voltage may be selected such that the charge carriers induced to move to the optical waveguide 102 may not be able to further tunnel through the dielectric layer 110. As a result, the tunneled charge carriers become effectively trapped within the optical waveguide 102 of the nonvolatile programmable passive optical structure 100. In this manner, the optical waveguide 102 functions as a floating gate, such as described above.

When voltage is removed from the control electrode 106, charge remains in the optical waveguide 102, affecting the refractive index thereof. In some cases, the optical waveguide 102 can include a doping pattern that induces any charge carriers in the optical waveguide 102 to concentrate in a particular region of the optical waveguide 102, such as in the rib/central region of the optical waveguide 102; this is not required of all embodiments.

In some cases, wings of the optical waveguide 102 can be implanted with charges so as to encourage charge accumulated within the optical waveguide 102 to congregate in the central region of that waveguide. For example, as shown in FIG. 1B, the optical waveguide 102 can include a first wing 102a and a second wing 102b flanking a central region 102c. As discussed above, the first wing 102a and the second wing 102b can each include defined thereon a raised region 118, which can increase manufacturing tolerances. In these examples, the raised regions 118 can be used as implant sites. In other cases, implantation may be performed in other regions different to and/or in addition to the regions shown. Once implants are disposed, local charge gradients may encourage any injected charge to congregate in the central region 102c, thereby increasing the effect of this electrical charge on light passing through the optical waveguide 102, and in particular, the effect on light passing through the central region 102c. As noted above, the implants may be positioned in a single location, multiple locations, or in a pattern (relative to, or defined in one or more reference planes). In some cases, implants may take a shape such as a shape following a perimeter of a floating gate as described herein. The implants can have any suitable charge polarity or combinations of charge polarities (e.g., regions of charge); a person of skill in the art will readily appreciate that many suitable configurations are possible.

As a result of the depicted construction(s), it may be understood that charge state of the optical waveguide 102 is a mutable nonvolatile property that does not require power to maintain. In turn, because the charge state influences the index of refraction of the optical waveguide 102 by the electro-optic effect, the index of refraction of the optical waveguide is also a mutable nonvolatile property that does not require power to maintain.

In this manner, the depicted structure is a nonvolatile passive optical structure having at least one optical property that is electrically programmable.

The foregoing embodiment depicted in FIGS. 1A-1B and the various alternatives thereof and variations thereto are presented, generally, for purposes of explanation, and to facilitate an understanding of various configurations and constructions of a nonvolatile programmable passive optical structure, such as described herein. However, it will be apparent to one skilled in the art that some of the specific details presented herein may not be required in order to practice a particular described embodiment, or an equivalent thereof.

For example, in other embodiments, proportions and relative dimensions of the layers of the nonvolatile programmable passive optical structure 100 may vary. In some cases, the wing regions of the optical waveguide may extend farther than shown; in other cases, the rib portion of the optical waveguide may take a different shape.

Further, it may be appreciated that the structure shown in FIG. 1 may be implemented to any suitable scale. In many embodiments, the structure may be a micrometer-scale structure, having a width of approximately 5 μm and a height of less than 1 μm. In other cases, other scales, cross-sectional profiles, relative sizes of different elements and layer thicknesses, and so on may be used.

In some cases, the optical waveguide may extend in a linear fashion (in or out of the page), whereas in other cases, the optical waveguide may be at least partially curved. In some cases, the optical waveguide may be optically coupled to one or more photonic circuits.

Furthermore, as noted above, one or more dimensions or dimensional properties of an optical waveguide as described herein may be selected to impart—when exhibiting a particular charge—a 180° phase shift relative to another parallel waveguide, such as may be included in an interferometer structure. In these examples, a charged state of the optical waveguide/floating gate corresponds to fully destructive interference (i.e., no light passing through the interferometer structure), whereas an uncharged state of the optical waveguide/floating gate corresponds to fully in-phase, constructive interference (i.e., passing light through the interferometer structure). In other constructions, light can selectively pass between different outputs based on different charge states.

In yet other examples, the silicon nitride layer disposed between the optical waveguide and the control gate can be leveraged as a second waveguide, coupled to a different (or the same) photonic circuit. In other cases, the silicon nitride layer may be disposed to a thickness unsuitable for waveguide operation.

In such embodiments, the floating gate/optical waveguide should be electrically decoupled from any electrical circuit or path to circuit or system ground, so that the floating gate/optical waveguide can maintain its charged state in a non-volatile manner. Such structures therefore are capable of transmitting light, but are electrically isolated.

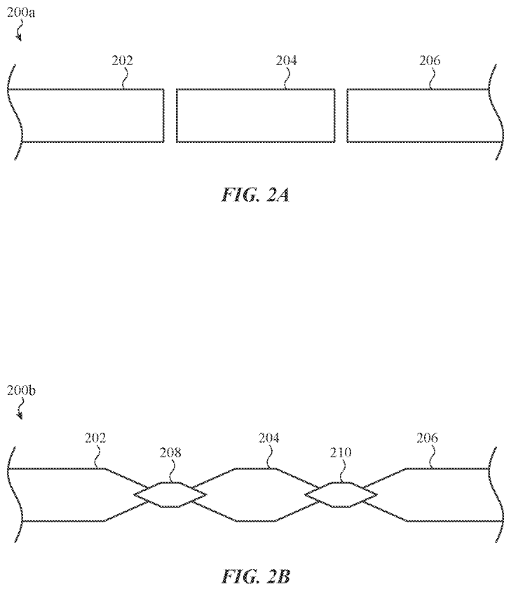

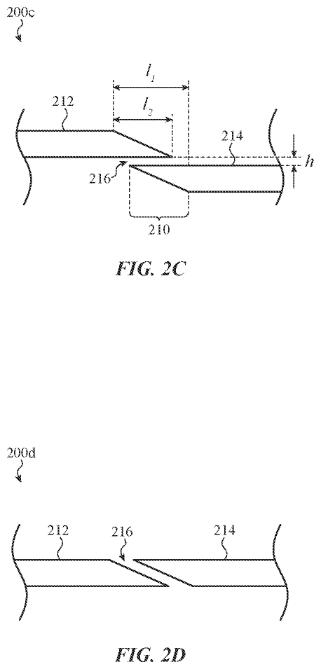

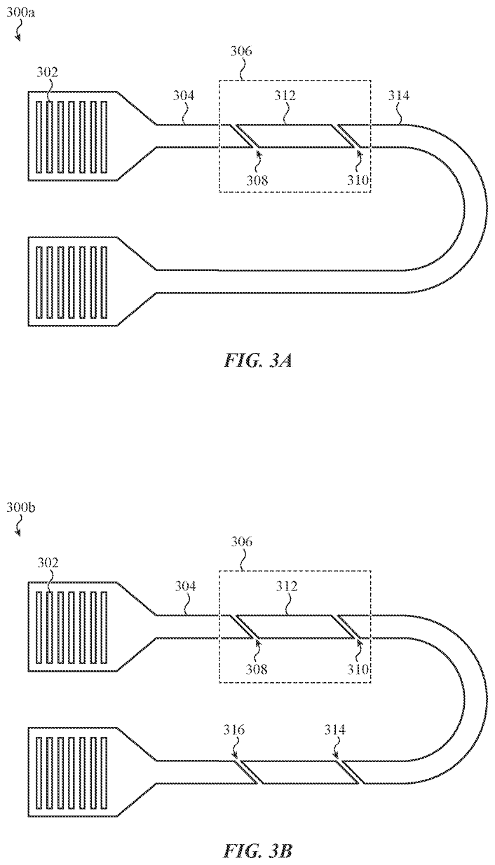

In one example construction, a waveguide optically coupling to a waveguide of a nonvolatile programmable passive optical structure as described herein can be segmented, such as shown in FIG. 2A. In this embodiment, a waveguide 200a can include a first segment 202 that is electrically decoupled from a second segment 204, that is in turn electrically decoupled from a third segment 206. In this example construction, each of the segments can be optically coupled due to relative proximity, while remaining conductively decoupled. More specifically, each of the illustrated segments can be separated by an insulator such as a silicon oxide. In this example, the second segment 204 may be a floating gate/optical waveguide of a nonvolatile programmable passive optical structure, such as a described herein.

In another example, an optical coupling can be formed by out-of-plane adiabatic tapers. FIG. 2B depicts a waveguide 200b that can include a first segment 202 that is electrically decoupled from a second segment 204, that is in turn electrically decoupled from a third segment 206, as with the embodiment shown in FIG. 2A. In this example construction, however, each of the segments include at least one adiabatic taper that overlaps with an optical jumper, such as the optical jumpers 208 and 210.

More specifically, the optical jumpers 208, 210 can also include corresponding adiabatic tapers and can be formed and/or disposed out of plane with the segments of the waveguide 200b. In this manner, light can pass through the waveguide 200b, crossing between different layers of material via overlapping adiabatic tapers. In this example, as with the embodiment shown in FIG. 2A, the various segments of the waveguide 200b are optically coupled, but conductively decoupled. More specifically, each of the illustrated segments can be separated by an insulator such as a silicon oxide. As with the embodiment shown in FIG. 2A, in this example, the second segment 204 may be a floating gate/optical waveguide of a nonvolatile programmable passive optical structure, such as described herein.

Other constructions are possible. For example, as shown in FIG. 2C, wedge-shaped transitions may be used to optically couple and conductively decouple two waveguide portions. For example, as shown in FIG. 2C, a waveguide 200c is segmented into two segments, a first segment 212 and a second segment 214. These segments may overlap for a distance 11 and each may include a tapered region 210, each taper respectively extending for a distance 12. The segments may be physically separated by a gap 216.

In some cases, tapering of the first segment 212 and the second segment 214 may extend for the same distance (e.g., the same angle), although this is not a necessary requirement of all embodiments. Similarly, in some cases, the overlap distance between the segments may be different than that which is shown. In some cases, the tapers may be positioned beside one another on the same substrate (e.g., the first segment 212 is offset to the left of the second segment 214). In other cases, the tapers may be positioned in different planes (e.g., the first segment 212 is above the second segment 214. In yet other examples, such as the waveguide 200d shown in FIG. 2D, the tapers may be mirrors of one another.

These foregoing embodiments depicted in FIGS. 1A-2D and the various alternatives thereof and variations thereto are presented, generally, for purposes of explanation, and to facilitate an understanding of various configurations and constructions of a nonvolatile programmable passive optical structure that includes a floating gate/optical waveguide, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

For example, generally and broadly, it may be appreciated that a nonvolatile programmable passive optical structure such as described in reference to FIGS. 1A-2D can be implemented in any number of suitable ways. In some examples, a source electrode can be positioned along or overlapping an edge of an optical waveguide/floating gate. In some examples, a control electrode can be positioned along or overlapping an edge of an optical waveguide/floating gate. In some cases, a control electrode can be positioned on one face of an optical waveguide (e.g., a bottom face) whereas a source electrode can be positioned on an opposite face of the same waveguide. In some cases, more than one optical waveguide/floating gate can be associated with the same control electrode/source electrode pair. In some cases, as noted above, a drain electrode can also be included to impart both electrical and optical read functionality to the nonvolatile programmable passive optical structure.

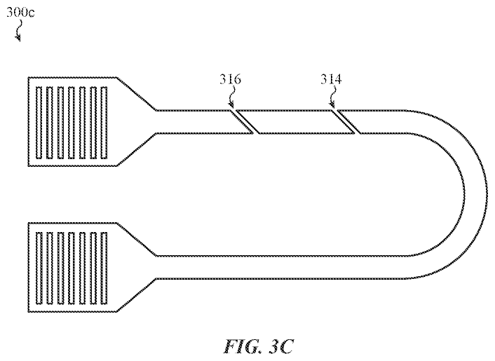

For example, FIG. 3A depicts an optical structure 300a that can include an optical coupling and a conductive break, such as described herein. In particular, the optical structure 300a includes an optical input and an optical output. The optical input can be provided by a grating coupler 302, configured to optically couple to in many examples an optical fiber. The grating coupler 302 can converge to a first segment 304 of a silicon waveguide (or other material) that in turn optically couples into a programmable optical structure 306 which includes two electrical isolation points defined by the gaps 308 and 310, which may also be referred to as isolation couplers. The gaps of the programmable optical structure 306 electrically isolate a second segment 312 from the first segment 304 and a third segment 314. As a result of this construction, the second segment 312 can be electrically floating while also being a portion of an optical path defined through the grating coupler 302, the first segment 304, the second segment 312, the third segment 314, and so on.

In other cases, multiple electrical breaks can be included. For example, as shown in FIG. 3B, an optical structure 300b includes an optical path that can originate at an optical input defined by the grating coupler 302. The optical path passes into a first segment 304 which is optically coupled to and electrically decoupled from a programmable optical structure 306. The programmable optical structure 306 includes gaps 308, 310 which electrically isolate a second segment 312 of the waveguide 300b. In addition, the waveguide 300b includes additional electrical isolations defined by the gaps 314 and 316 (isolation couplers). The depicted number of breaks need not be limited to those shown; any suitable number of breaks may be made so as to electrically isolate any suitable portion of the waveguide 300b. In this example, any section that is electrically isolated (e.g., floating) can be used as a floating gate, such as described herein. In some constructions, a single optical path can pass through multiple floating gates, such as described herein.

In further embodiments, one or more gaps may be filled with a dielectric material, such as shown within the gap 316 of the waveguide 300c as shown in FIG. 3C. In some cases, all gaps may be backfilled with a dielectric material, whereas in other cases, only a subset of all gaps are filled with a material. For example, the gap 318 of FIG. 3C is not filled.

These foregoing embodiments depicted in FIGS. 3A-3C and the various alternatives thereof and variations thereto are presented, generally, for purposes of explanation, and to facilitate an understanding of various configurations and constructions of a nonvolatile programmable passive optical structure that includes an optical coupling and an electrical discontinuity, break, or other insulating gap, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

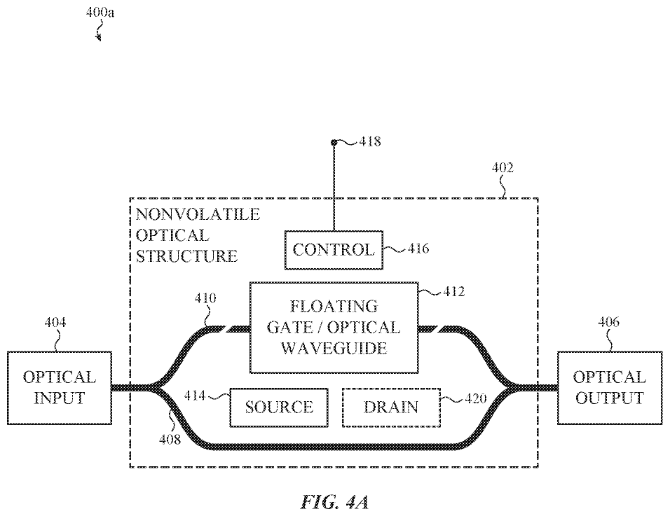

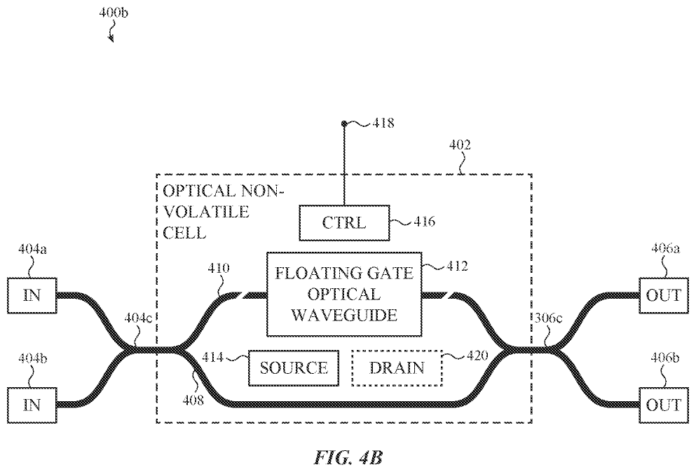

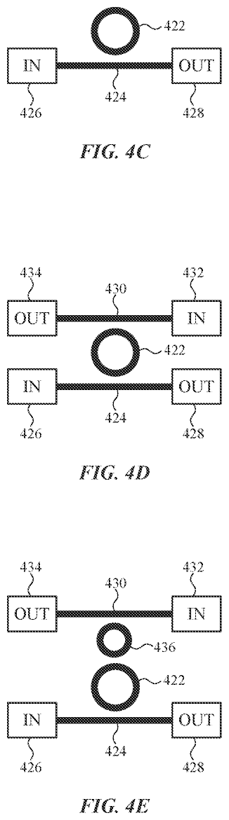

FIG. 4A depicts a system diagram 400a of a nonvolatile programmable passive optical structure for a photonic circuit, as described herein. The nonvolatile programmable passive optical structure 402 receives light from an optical input 404 and provides output to further photonic elements or circuits via an optical output 406.

The nonvolatile programmable passive optical structure 402 is depicted as implementing an interferometer structure, although this is not required of all embodiments. In other cases, ring resonators, delay loops, and other optical waveguides or optical/photonic structures can be included.

The interferometer structure is defined by a split or bifurcation of the optical input 404 into a first arm 408 and a second arm 410. The first arm 408 may also be referred to as the reference arm and the second arm may also be referred to as a mutable arm.

In this example, the second arm 410 is configured to optically couple through a floating gate/optical waveguide 412 that may be configured as described above with reference to FIGS. 1A-4C. The floating gate/optical waveguide 412 may be fully encapsulated in an insulator layer, such as silicon oxide. Nevertheless, the floating gate/optical waveguide 412 may be optically coupled to the second arm 410.

The floating gate/optical waveguide 412 may be formed adjacent to a source electrode 414 and a control electrode 416, which may be configured to operate as described above. More particularly, in this construction, when a voltage signal—such as a programming signal or an erase signal—is received by the nonvolatile programmable passive optical structure 402 at a signaling input 418, the control electrode 416 can be driven to a specified voltage which, in turn, can cause charge to accumulate in the floating gate/optical waveguide 412 due to tunneling through the insulator layer separating the source electrode 414 from the floating gate/optical waveguide 412.

Once charge is accumulated in the floating gate/optical waveguide 412, an effective group refractive index of the second arm 410 is changed, which in turn changes the phase of light passing through the second arm 410 relative to the reference arm.

As a result, when light passing through the mutable arm is recombined with light passing through the reference arm prior to the optical output 406, the difference in phase results in destructive interference, attenuating light output from the optical output 406 relative to an amplitude of light provided as input to the optical input 404. As noted above, by controlling the dimensions (e.g., length, width, shape, and so on) of the floating gate/optical waveguide 412 and the charge applied thereto, any suitable phase difference can be achieved, including a 180° phase difference which, as known to a person of skill in the art, effectively prevents any light from passing through the optical output 406.

In this manner, the nonvolatile programmable passive optical structure 402 can be used as a nonvolatile, low-power, optical memory cell or nonvolatile optical switch.

These foregoing embodiments depicted in FIGS. 1A-4A and the various alternatives thereof and variations thereto are presented, generally, for purposes of explanation, and to facilitate an understanding of various configurations and constructions of a nonvolatile programmable passive optical structure, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

For example, as noted above, in some examples a drain electrode 420 can also be included. Measuring a voltage between the drain electrode 420 and the source electrode 414 can probe a charge state of the floating gate/optical waveguide 412. In this manner, the drain electrode 420 can be used to verify that charge has been correctly applied to the floating gate/optical waveguide 412 and/or as an electronic bit of digital memory. In another, non-limiting phrasing, the drain electrode can be used as a redundant electrical method of determining the nonvolatile charge state of the floating gate/optical waveguide 412. In some cases, the drain may also exist in the underlying substrate. In some cases, this may improve the apparent speed at which a memory cell as described herein operates; in a first mode, while the floating gate/optical waveguide is charging and/or being programmed, the drain electrode 420 may be used as a digital non-volatile bit in a semiconductor circuit. Once the floating gate is fully charged, the drain electrode 420 may be no longer required and/or used; the circuit may be read optically only thereafter. It may be appreciated that these constructions are mere examples; in other cases, other methods and/or mutual electrical and optical operations may be performed with a structure as described and depicted herein.

Furthermore, as noted above, in some cases an interferometer structure with multiple inputs and multiple outputs can be constructed.

For example, as with other embodiments presented herein, FIG. 4B depicts a system diagram 400b of a nonvolatile programmable passive optical structure for a photonic circuit, as described herein. The nonvolatile programmable passive optical structure 402 receives light from the optical inputs 404a, 404b and provides output to further photonic elements or circuits via optical outputs 406a, 406b. The optical inputs 404a, 404b can be coupled together at a junction, also referred to as a coupler 404c.

As with the embodiment shown in FIG. 4A, the interferometer structure depicted in FIG. 4B can include a split or bifurcation of an output of the coupler 404c into a first arm 408 and a second arm 410. The first arm 408 may also be referred to as the reference arm and the second arm may also be referred to as a mutable arm, control arm, floating gate arm, and so on.

In this example, as with other examples presented herein, the second arm 410 is configured to optically couple through a floating gate/optical waveguide 412 that may be configured as described above with reference to FIGS. 1A-4A. The floating gate/optical waveguide 412 may be fully encapsulated in an insulator layer, such as a silicon oxide, electrically decoupling the floating gate/optical waveguide 412 from other electrical components. Although conductively decoupled from other circuitry or path(s) to ground, the floating gate/optical waveguide 412 may be optically coupled to (or into) the second arm 410.

The floating gate/optical waveguide 412 may be formed adjacent to a source electrode 414 and a control electrode 416, which may be configured to operate as described above. More particularly, in this construction, when a voltage signal—such as a programming signal or an erase signal—is received by the nonvolatile programmable passive optical structure 402 at a signaling input 418, the control electrode 416 can be driven to a specified voltage which, in turn, can cause charge to accumulate in the floating gate/optical waveguide 412 due to tunneling through the insulator layer separating the source electrode 414 from the floating gate/optical waveguide 412.

Once charge is accumulated in the floating gate/optical waveguide 412, an effective group refractive index of the second arm 410 is changed, which in turn changes the phase of light passing through the second arm 410 relative to the reference arm.

As a result, when light passing through the mutable arm is recombined by a second coupler 406c with light passing through the reference arm prior to the optical outputs 406a, 406b, the difference in phase results in destructive or constructive interference, dividing power of light input to the optical inputs 404a, 404b between the optical outputs 406a, 406b in a ratio related to the charge state of the floating gate/optical waveguide 412. As noted above, by controlling the dimensions (e.g., length, width, shape, and so on) of the floating gate/optical waveguide 412 and the charge applied thereto via programming, any suitable phase difference between the first arm 408 and the second arm 410 can be achieved, and thus different power output can be provided via each optical output of the optical outputs 406a, 406b. As depicted, the floating gate/optical waveguide 412 is conductively isolated from other elements of the depicted structure.

In this manner, the nonvolatile programmable passive optical structure 402 can be used as a nonvolatile, low-power, optical memory cell, optical hidden layer nodes of a trained neural network, nonvolatile optical switch, and so on. It may be appreciated that the optical structure 402 can take a number of suitable dimensions. In particular, different functional elements of the optical structure 402 can take any suitable dimensions which may vary from embodiment to embodiment. For example, a control gate of a structure as described herein can take a number of shapes, sizes, and structures. In addition, a source gate as described herein can take a number of suitable shapes, sizes, and structures. Further still, a floating gate as described herein can take a number of suitable shapes, sizes, and dimensions.

As with the embodiment shown in FIG. 4A, the optical structure shown in FIG. 4B can also optionally include a drain electrode 420, configured as described above or in another suitable manner. This description is not repeated.

These foregoing embodiments depicted in FIGS. 4A-4B and the various alternatives thereof and variations thereto are presented, generally, for purposes of explanation, and to facilitate an understanding of various configurations and constructions of a nonvolatile programmable passive optical structure, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

For example, as noted above, in some cases optical structures that are not interferometer structures can be used. As one example, a ring resonator may be used. FIGS. 4C-4E depict example ring resonator constructions.

FIG. 4C depicts a ring resonator 422. The ring resonator 422 is positioned to optically couple to a waveguide 424 that receives light from an input 426 and provides light as output through an output 428. As known to a person of skill in the art, optical and mechanical properties of the ring resonator 422 define what frequencies resonate through successive trips round the ring resonator 422. For example, larger ring resonators (having a larger radius or defining a longer path) resonate at different low frequencies than smaller ring resonators. In addition, differently structured ring resonators may resonate with different harmonics. As known to a person of skill in the art, heaters may be used to change one or more dimensions of a ring resonator by thermal expansion. For simplicity of description and illustration FIG. 4C is depicted without heating elements that may be used in certain embodiments.

In addition to, or in place of, changing one or more mechanical properties of a ring resonator, such as the ring resonator 422, the ring resonator 422 may be a floating gate/optical waveguide such as described herein. More specifically, the ring resonator 422 may be electrically decoupled from other circuitry (and system and circuit ground) but optically coupled to the waveguide 424. In this manner, as with other optical structures described herein, a charge state of the ring resonator 422 defines what frequencies resonate through the ring resonator 422 and, thus, what frequencies are filtered and/or reflected within the waveguide 424 as a result of optical coupling with the ring resonator 422.

In some constructions, the ring resonator 422 can optically couple to multiple waveguides. For example, as shown in FIG. 4D, the ring resonator 422—which may also be and/or may be optically coupled to a floating gate/waveguide, as described herein—can be optically coupled to (e.g., positioned close to) a second waveguide 430 that receives optical input via a second optical input 432 and provides output via a second optical output 434. In some cases, optical input via the second optical input 432 may not be required; light from the first waveguide—the waveguide 424—may couple into the ring resonator 422, resonate at one or more frequencies, and couple into the second waveguide 430.

In these constructions, very specific and narrow bands of light (e.g., light at particular frequencies) can be passed to the second output 434. In these constructions, as described above in reference to FIG. 4C, the ring resonator 422 can be, or can be optically coupled to, a floating gate/waveguide as described herein. In this manner, a charge state of the ring resonator 422 which may be established via programming as described above, defines what frequencies of light are output by the second output 434, what frequencies of light are filtered from the output 428, and/or what frequencies of light are reflected back in a direction opposite of the input 426. By changing the charge state, power output and frequency output from each optical output can be precisely controlled and maintained in a non-volatile manner.

In yet other cases, multiple ring resonators can be chained and/or optically coupled together. For example, as shown in FIG. 4E, a second ring resonator 436 can be optically coupled to the ring resonator 422. In this construction, a higher-frequency harmonic that resonates within the first ring resonator 422 can be coupled into the second ring resonator 436 and, in turn, coupled into the second waveguide 430.

In some cases, a floating gate/waveguide as described herein can be used with one or more other control elements, such as heating elements and the like.

Further still, in some cases, multiple nonvolatile programmable passive optical structures can be combined to create higher-order programmable optical structures. For example, as noted above, in some embodiments, multiple nonvolatile programmable passive optical structures can be arranged in an optical network and can each be uniquely programmed to impart different attenuation (a different phase difference resulting from different programming) corresponding to different hidden layer nodes of a trained neural network.

These foregoing embodiments depicted in FIGS. 4A-4E and the various alternatives thereof and variations thereto are presented, generally, for purposes of explanation, and to facilitate an understanding of various configurations and constructions of a nonvolatile programmable passive optical structure, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

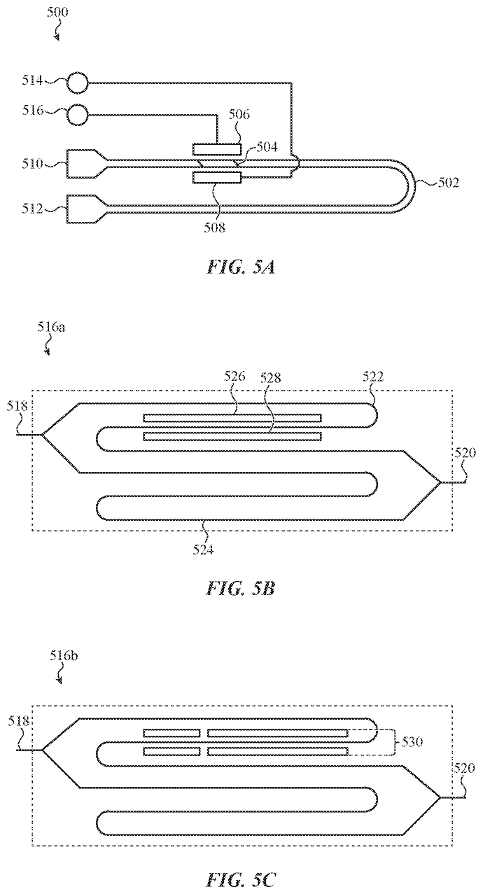

For example, FIG. 5A depicts a simplified schematic diagram of a switchable optical element, as described herein. The optical element 500 includes a waveguide 502 that includes an electrically isolated segment 504 within a path defined by the waveguide 502. In this construction, a source electrode 506 and a control electrode 508 can be operated in cooperation to drive the electrically isolated segment 504 to a particular voltage, leveraging techniques such as described herein. In this manner, light passing along the optical path may be influenced and/or changed as it passes through the electrically isolated segment 504 (e.g., phase shift).

More specifically, light provided as input to the optical element 500 at an optical input 510 may be influenced by the charge state of the electrically isolated segment 504 before traversing through an entirety of the waveguide 502 and exiting the optical element 500 at an optical output 512. The charge state of the electrically isolated segment 504 can be controlled by providing appropriate electrical signals to the control electrode 508 and the source electrode 506 via the electrical contacts 514, 516. More specifically, the optical element 500 includes both electrical inputs and optical inputs and outputs. By providing appropriate signals to the electrical inputs, controllable augmentation of light provided as input to the optical input is achieved.

These optical element constructions, as noted above, can be included in higher order and/or purpose-configured photonic or optical circuits. One such example is an MZI, such as shown in FIG. 5B. In this example, an MZI 516a may define two branching optical paths. In particular, an optical input 518 may receive input light (which may be laser pulses, such as infrared laser pulses), which is thereafter split into two paths. One of the two paths passes through a floating electrode/waveguide segment as described herein and the other path does not. Light from the two paths is recombined and provided as output via the optical output 520.

In particular, the first path may be defined by a first waveguide 522. The second path may be defined by a second waveguide 524. The first waveguide 522 includes a segment that can be charged or discharged by operation of a source electrode 526 and a control electrode 528. In this manner, the charge state of the segment defines optical characteristics of light provided as output via the optical output 520.

In other embodiments, more than one set of source electrodes or control electrodes may be used. For example, as shown in FIG. 5C, multiple electrodes 530—which may be of different size and/or area—can charge or discharge the same or different segments of one or more portions of a waveguide, such as described herein.

These foregoing embodiments depicted in FIGS. 5A-5C and the various alternatives thereof and variations thereto are presented, generally, for purposes of explanation, and to facilitate an understanding of various configurations and constructions of a nonvolatile programmable passive optical structure, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

For example, although the example embodiments depict MZI constructions, it may be appreciated that this is merely one example.

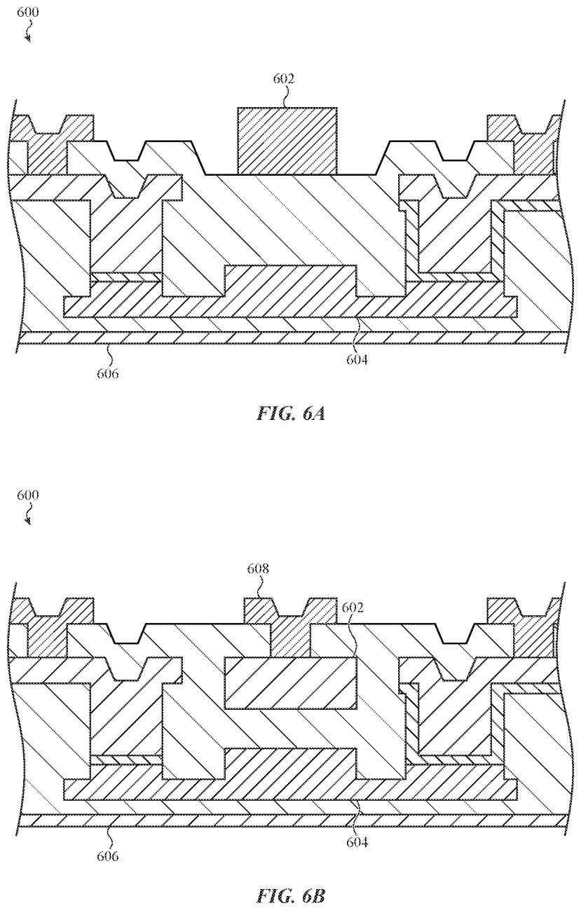

In some embodiments, an optical element as described herein can be provided with one or more active or passive electric charge exhibiting elements. The charge exhibiting elements can be durably or temporarily electrically charged so as to influence charge distribution within a floating gate/optical waveguide as described herein. Presence of such charge may induce concentration of charge deposited in a floating gate/optical waveguide as described herein in a central region thereof, thereby improving optical effects. For example, an optical element 600 as shown in FIG. 6A, may include an electrode 602 that may be driven to a voltage so as to charge the electrode 602 in opposite polarity from the floating gate electrode/waveguide 604, thereby attracting charge stored in the floating gate electrode/waveguide 604. Once the electrode 602 is charged, charges within the floating gate electrode/waveguide 604 may be drawn into the central waveguide region of the floating gate electrode/waveguide 604.

In other cases, a second electrode 606 may be charged to the same polarity as the floating gate electrode/waveguide 604. In this example, the second electrode 606 may repel charge within the floating gate electrode/waveguide 604 so that charge accumulates in the central region of the floating gate electrode/waveguide 604.

These examples are not exhaustive. In some cases, implants may be used to influence distribution of deposited charge in a floating gate electrode/waveguide, such as the floating gate electrode/waveguide 604 as described herein. In other cases, implants and/or chargeable electrodes may be used. In some cases, the electrode 606 may be configured to attract charge, and/or the electrode 602 may be configured to repel charge. It may be appreciated that many configurations and constructions are possible. For example, as shown in FIG. 6B, the electrode 602 may be buried within cladding, and conductively coupled to control circuity via a dedicated conductive coupling 608.

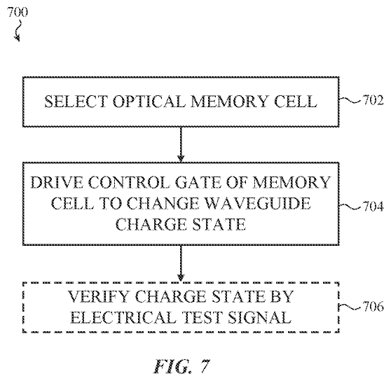

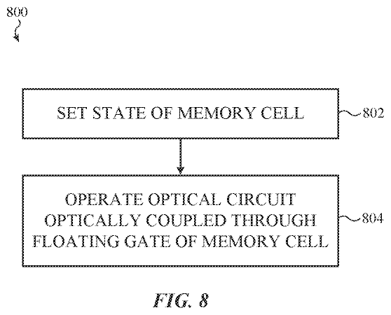

FIG. 7 is a flowchart depicting example operations of a method of operating a nonvolatile programmable passive optical structure as a memory cell, such as described herein. The method 700 includes operation 702 at which a particular memory cell is selected from a group of memory cells. The memory cell may be selected by address, in some examples.

The method further includes operation 704 in which a control gate or control electrode associated with the memory cell can be driven to a particular voltage to change the charge state of a floating gate/waveguide associated with the memory cell.

Optionally, the method 700 can further include operation 706 at which a drain electrode/gate can be leveraged together with a source electrode/gate to electrically determine a charge state of the floating gate/waveguide. This may not be required of all embodiments.

FIG. 8 is a flowchart depicting example operations of a method of operating a nonvolatile programmable passive optical structure with a photonic circuit, such as described herein. The method 800 includes operation 802 at which a particular memory cell is selected from a group of memory cells, such as by addressing. In addition, the selected memory cell is programmed to a particular charge state or, more generally, set to a particular digital value. Next, at operation 804, an optical circuit or photonic circuit optically coupled through a floating gate/waveguide of the memory cell can be operated. More simply, light can be passed through the floating gate, which may be affected by the charge state set at operation 802.

One may appreciate that although many embodiments are disclosed above, that the operations and steps presented with respect to methods and techniques described herein are meant as exemplary and accordingly are not exhaustive. One may further appreciate that alternate step order or fewer or additional operations may be required or desired for particular embodiments.

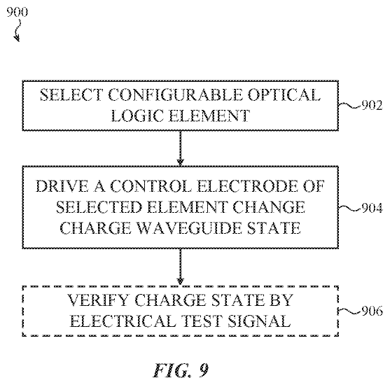

FIG. 9 is a flowchart corresponding to a method of writing data to a memory cell of a photonic circuit element, such as described herein. More specifically, the method 900 relates to changing an operational mode of an optical logic element, such as a logic gate, memory cell, or other logical circuit element implemented at least in part with photonic elements. The method includes operation 902 at which a particular optical logic element is selected among a set of optical logic elements. Next, at operation 904, a control electrode of the selected optical logic gate can be driven to a particular voltage so as to induce a charge in a floating gate/waveguide of the optical logic element. Thereafter, at operation 906, the charge state of the floating gate/waveguide can be verified by applying an electrical test signal to one of a control gate, a source gate, or a drain gate of the optical logic element.

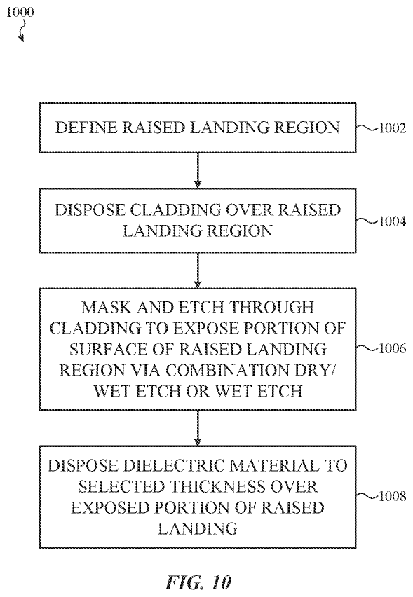

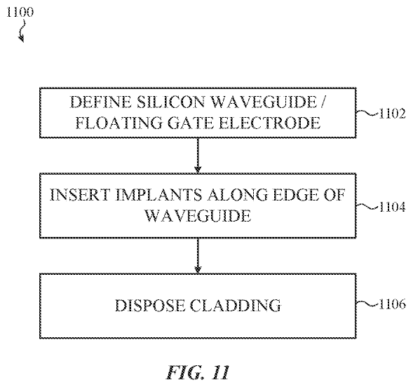

FIG. 10 is a flowchart that corresponds to a method of manufacturing an optical element as described herein. The method 1000 includes operation 1002 at which a silicon waveguide is formed to include at least two wings, abutting a (strip, in many examples) waveguide portion of the silicon waveguide. Along these wings of the silicon waveguide, table portions (also referred to as mesa portions or raised features) can be formed.

Next, at operation 1004, the silicon waveguide with raised regions or features can be encased, buried, or otherwise disposed within a cladding such as silicon dioxide. Thereafter, at operation 1006, photolithography operations can be initiated in which one or more vias through the cladding are etched in a combination of dry and/or wet etch procedures. In some examples, wet etch may be used to finish the etch to expose an upper surface of the raised portions of the silicon waveguide.

Finally, at operation 1008, a dielectric material can be disposed over the exposed upper surface of the raised portions so as to electrically isolate the silicon waveguide from other circuits. In other words, the silicon waveguide is conductively decoupled from other circuitry that may be associated with the optical element.

Still other methods described herein relate to implantation. In particular, FIG. 11 depicts a flowchart corresponding to a method of manufacturing an optical structure as described herein. In particular, the method 1100 includes operation 1102 at which a silicon waveguide/floating gate electrode can be formed with a suitable technique, such as those described above or others that may be known to a person of skill in the art. Next at operation 1104, one or more implantation operations may be performed at particular, selected, regions of the silicon waveguide. The positions of the implants may be selected so as to encourage charge carriers within the silicon waveguide to aggregate/congregate in an optical path defined by the waveguide.

Thereafter, at operation 1106, the implanted silicon waveguide may be buried in a cladding.

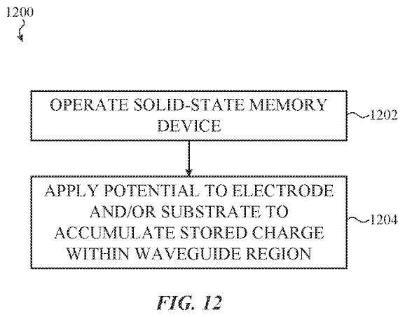

FIG. 12 depicts another method of operating a device as described herein. In this embodiment, however, in addition to or in place of implants implanted during manufacturing, one or more electrodes can be used to temporarily move accumulated charge to a particular location within the silicon waveguide. For example, the method 1200 includes operation 1202 at which an instruction to operate a solid state memory device such as described herein is received. In response to the instruction, at operation 1204, a voltage may be applied to an electrode and/or to a conductive portion of a base substrate so as to encourage charge accumulated within a floating electrode nearby thereto to concentrate within an optical path defined by the optical waveguide.

Although the disclosure above is described in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the some embodiments of the invention, whether or not such embodiments are described and whether or not such features are presented as being a part of a described embodiment. Thus, the breadth and scope of the present invention should not be limited by any of the above-described exemplary embodiments but is instead defined by the claims herein presented.

As used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

What is claimed is:

1. A nonvolatile memory comprising:
an array of nonvolatile charge storage cells, each nonvolatile charge storage cell comprising:
a source gate;
a control gate;
a silicon substrate defining:
a first wing;
a second wing; and
a first waveguide between the first wing and the second wing, the first waveguide configured to accumulate and retain electrical charge supplied by the source gate in response to a voltage applied to the control gate, the first waveguide defining:
an optical input; and
an optical output; and
a second waveguide optically coupled to the first waveguide and conductively decoupled from the silicon substrate, the source gate, and the control gate.

2. The nonvolatile memory of claim 1, the first wing comprising an elevated portion separated from the source gate by an insulator layer.

3. The nonvolatile memory of claim 2, wherein:
the insulator layer is a first insulator layer;
the elevated portion is a first elevated portion; and
the second wing comprises a second elevated portion separated from the control gate by a second insulator layer.

4. The nonvolatile memory of claim 1, comprising an isolation coupler optically coupling the second waveguide to the first waveguide and conductively decoupling the second waveguide form the first waveguide.

5. The nonvolatile memory of claim 4, wherein the isolation coupler comprises a tapered region.

6. The nonvolatile memory of claim 4, wherein the isolation coupler comprises a gap.

7. The nonvolatile memory of claim 1, comprising a first isolation coupler optically coupling the second waveguide to the first waveguide and a second isolation coupler optically coupling the first waveguide to a third waveguide.

8. The nonvolatile memory of claim 1, comprising an electrode positioned adjacent to the first waveguide.

9. The nonvolatile memory of claim 8, wherein the electrode is disposed below the first waveguide.

10. The nonvolatile memory of claim 8, wherein a voltage applied to the electrode attracts charge accumulated in the first waveguide toward the electrode.

11. The nonvolatile memory of claim 1, comprising an implant disposed adjacent to the first waveguide so as to influence a charge distribution of charge accumulated in the first waveguide.

12. A nonvolatile memory for a photonic circuit, the nonvolatile memory comprising:
an optical input;
an optical output;
a floating gate waveguide;
a control gate;
a source gate;
a first isolation coupler optically coupling the optical input to the floating gate waveguide, the first isolation coupler conductively decoupling the floating gate waveguide from the optical input; and
a second isolation coupler optically coupling the floating gate waveguide to the optical output, the second isolation coupler conductively decoupling the floating gate waveguide from the optical input; wherein the floating gate waveguide is configured to accumulate and retain electrical charge supplied by the source gate in response to a voltage applied to the control gate.

13. The nonvolatile memory of claim 12, wherein the floating gate waveguide is a portion of an interferometer or a resonator.

14. The nonvolatile memory of claim 13, wherein accumulated charge in the floating gate waveguide influences a behavior of the interferometer or the resonator.

15. The nonvolatile memory of claim 12, wherein the first isolation coupler comprises a gap.

16. The nonvolatile memory of claim 12, wherein the second isolation coupler comprises a tapered gap.

17. The nonvolatile memory of claim 12, wherein the floating gate waveguide is formed from a semiconductor.

18. A nonvolatile memory for a photonic circuit, the nonvolatile memory comprising:
a floating gate waveguide;
a control gate;
a source gate;
a first isolation coupler conductively isolating the floating gate waveguide from the control gate and the source gate; and
a second isolation coupler conductively isolating the floating gate waveguide from the control gate and the source gate; wherein the floating gate waveguide is configured to accumulate and retain electrical charge supplied by the source gate in response to a voltage applied to the control gate.

19. The nonvolatile memory of claim 18, wherein the floating gate waveguide is formed from a semiconductor material.

20. The nonvolatile memory of claim 18, wherein the floating gate waveguide is optically coupled to a photonic circuit.
